(19) United States
(12) Patent Application Publication
(10) Pub. No.: US 2023/0096345 A1
(43) Pub. Date: Mar. 30, 2023

(54) Phone Case with Thermal Ground Plane

(71) Applicant: Kelvin Thermal Technologies, Inc., Boulder, CO (US)

(72) Inventors: Ryan J. Lewis, Boulder, CO (US); Jason W. West, Broomfield, CO (US); Daniel Katzman, Boulder, CO (US); Hunter Hach, Boulder, CO (US); Keller Lofgren, Boulder, CO (US)

(21) Appl. No.: 17/951,075

(22) Filed: Sep. 22, 2022

Related U.S. Application Data
(60) Provisional application No. 63/249,284, filed on Sep. 28, 2021.

(51) Int. Cl. H05K 7/20; H04B 1/3888; A45C 11/00

(52) U.S. Cl. CPC H05K 7/20472; H04B 1/3888; A45C 11/00; A45C 2011/002

(57) ABSTRACT

A phone case with a phone case body and a thermal ground plane is disclosed. The phone case, for example, may include fin that folds, bends, and/or extends outward from the phone case body. The phone case, for example, may include a magnetic area that comprises a toroid or donut shape. The phone case, for example, may include an aperture that extends through the phone case body and/or the thermal ground plane. The thermal ground plane may include a first casing; a liquid transport layer comprising a mesh or an array of pillars; a vapor transport layer comprising a mesh or an array of pillars; and a second casing, an outer periphery of the first casing and an outer periphery of the second casing are sealed together encasing the liquid transport layer, the vapor transport layer, and a heat transfer fluid.

### BACKGROUND

Some smartphones can develop hotspots during use that can be felt on the back surface and/or the front screen. Often, these hotspots occur when the smartphone is used for computationally intensive tasks such as, for example, 3D games, AR/VR, etc.; during high mobile data transfer; or other intense use. Hotspots may be ergonomically uncomfortable due to both the absolute temperature and the perceived temperature difference between the hotspot and other portions of the case. Smartphones are typically cooled by convection from the ambient air. And the heat a phone dissipates by convection may limit the power that drives the internal electronics and/or the speed of the internal clock. To compensate, some electronics may be throttled based on the temperature of the phone rather than based on the power, the clock speed, or other limitation.

### SUMMARY

A phone case is disclosed that includes a phone case body and a thermal ground plane. The thermal ground plane may be embedded within the phone case body or coupled with the phone case body. The thermal ground plane, for example, may include a first casing; a liquid transport layer comprising a mesh or an array of pillars; a vapor transport layer comprising a mesh or an array of pillars; and a second casing, an outer periphery of the first casing and an outer periphery of the second casing are sealed together encasing the liquid transport layer, the vapor transport layer, and a heat transfer fluid.

The phone case may include a fin that folds or bends outward from the phone case body.

The phone case may include a magnetic area that comprises a toroid or donut shape. The magnetic area, for example, may be coupled with a magnetic coupler within a phone. The phone case may include one or more wireless charging antennas.

The thermal ground plane may include an area without a metal that aligns with a wireless charging area of a phone. The thermal ground plane may include an area comprising a dielectric or RF-transparent material. The area, for example, may align with a wireless charging area of a phone.

The phone case may include a handle extending from the back of the phone case.

Another phone case is disclosed that includes a phone case body; a thermal ground plane coupled with a surface of the phone case body; and an aperture that extends through the phone case body and the thermal ground plane for a camera.

The phone case may include a magnetic area. The magnetic area may include a toroid or donut shape that surrounds the aperture.

The phone case, for example, may include one or more wireless charging antennas.

The thermal ground plane, for example, may include an area without a metal. The area, for example, may align with a wireless charging area of a phone.

The thermal ground plane, for example, may include an area comprising a dielectric or

RF-transparent material.

The phone case, for example, may include a handle extending from the back of the phone case.

Another phone case is disclosed that includes a phone case body; a magnetic area; and a thermal ground plane coupled with a surface of the phone case body. The magnetic area, for example, may include a toroid or donut shape. The magnetic area, for example, may be configured to couple with a magnetic coupler within a phone. The phone case body, for example, may include a substantially flat portion and sides configured to wrap around a phone.

The phone case, for example, may include one or more wireless charging antennas.

The phone case, for example, may include an area without a metal. The area, for example, may be configured to align with a wireless charging area of a phone.

The thermal ground plane, for example, may include an area comprising a dielectric or RF-transparent material. The area, for example, may be configured to align with a wireless charging area of a phone.

The phone case, for example, may include a handle extending from the back of the phone case.

### BRIEF DESCRIPTION OF THE FIGURES

FIG. 1 illustrates a thermal ground plane embedded within a phone case.

FIG. 2 illustrates a thermal ground plane embedded within a phone case.

FIG. 3 illustrates a thermal ground plane embedded within a phone case.

FIG. 4 illustrates an example phone carrier that may be attached with a phone case or directly with a phone.

FIG. 5A, FIG. 5B, and FIG. 5C illustrate an example phone case with elastic-actuated clips.

FIG. 6A illustrates an example phone with a wireless charging region and a camera.

FIG. 6B illustrates thermal ground plane that accommodates the wireless charging region and/or the camera.

FIG. 7A and FIG. 7B illustrate an example thermal ground plane with a transmitter antenna and/or a receiver antenna.

FIG. 8 illustrates an example extended area thermal ground plane.

FIG. 9 illustrates an example thermal ground plane with a plurality of fins that may increase the surface area of the thermal ground plane.

FIG. 10A illustrates an example thermal ground plane that includes detachable heat sink.

FIG. 10B illustrates an example detachable heat sink that includes a folded thermal ground plane and/or a plurality of fins.

FIG. 11 illustrates an example thermal ground plane with a plurality of detachable fins.

FIG. 12 illustrates an example phone case that can be magnetically attached with a detachable heat sink.

FIG. 13A and FIG. 13B illustrate an example foldable thermal ground plane with a foldable extended area.

FIG. 14A, FIG. 14B, FIG. 14C, and FIG. 14D illustrate an example foldable thermal ground plane with multiple folds.

FIG. 15A and FIG. 15B illustrate an example foldable case that may include a thermal ground plane sandwiched between a top layer and a bottom layer.

FIG. 16A and FIG. 16B illustrate example trapezoidal segments with pivot.

FIG. 17A and FIG. 17B illustrate example foldable thermal ground planes with a complicated mechanism.

FIG. 18 illustrates two example thermal ground planes with multiple fingers and/or fins laying opposite and about each other when flat that may unfold to increase surface area.

FIG. 19 illustrates an example phone case with a thermal ground plane and an integrated fan.

FIG. 20A and FIG. 20B illustrate an example fan folded out in one direction while folding thermal ground planes create fold-out fins in a perpendicular direction.

FIG. 21 illustrates an example thermal ground plane with an integrated thermoelectric cooler.

FIG. 22 illustrates an example detachable thermoelectric cooler coupled with thermal ground plane.

FIG. 23 illustrates an example heatsink for a thermoelectric cooler.

FIG. 24A illustrates an example detachable unit that includes phase change material and a thermally conductive material.

FIG. 24B illustrates an example detachable unit coupled with the case.

FIG. 25A illustrates an example thermal ground plane may be coupled with a vessel that is filled with a low-boiling-point material.

FIG. 25B illustrates an example expanded vessel.

FIG. 26 is a side view illustration of an example thermal ground plane.

FIG. 27 is a side-view of an example foldable device with a thermal ground plane having a foldable region that is attached with the thermal ground plane via a stretchable material.

### DETAILED DESCRIPTION

This disclosure describes a number of examples of phone cases with a thermal ground plane (TGP) that can improve cooling of a phone incased within the phone case. A phone case, for example, may include an extendable surface.

For example, a foldable TGP can be included in a foldable case. The heat dissipated from the phone can be transferred to the foldable case effectively through the foldable TGP. The maximum allowable power dissipation of a phone, for example, can be proportional to the total surface area exposed to natural air convection and radiation. The total surface area including the casing can be increased by about 2 to 4 times.

Heat, for example, may be transferred from a phone to a case in which the phone is incased. A case, for example, may serve as an extended surface for enhanced cooling, which may increase the effective thermal conductivity of case. With a foldable TGP, the heat transfer in the extended surface, e.g., or the case, may increase the thermal conductivity. Some example thermal ground planes disclosed in this document may have an effective thermal conductivity of about 6,000 W/mK or higher, which may be about 30,000 times higher than a polymer's thermal conductivity of about 0.2 W/mK.

Various types and arrangements of extended surfaces are disclosed that may be used with a phone or any other electronic device. Other examples of an extended surface that can be used with a phone may include, for example: a) a large foldable cooling pad, which, for example, may be as large as 100 cm×100 cm in the horizontal direction; b) a foldable cooling pad with multiple folds to reduce the footprint in the horizontal direction; c) a foldable cooling pad with multiple folds in the vertical direction for the minimum footprint in the horizontal plane; or d) any combination of a), b) and c).

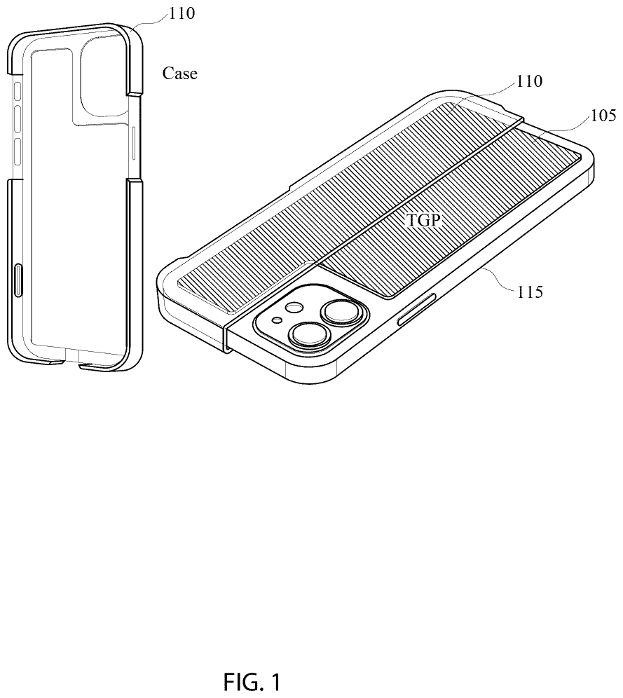

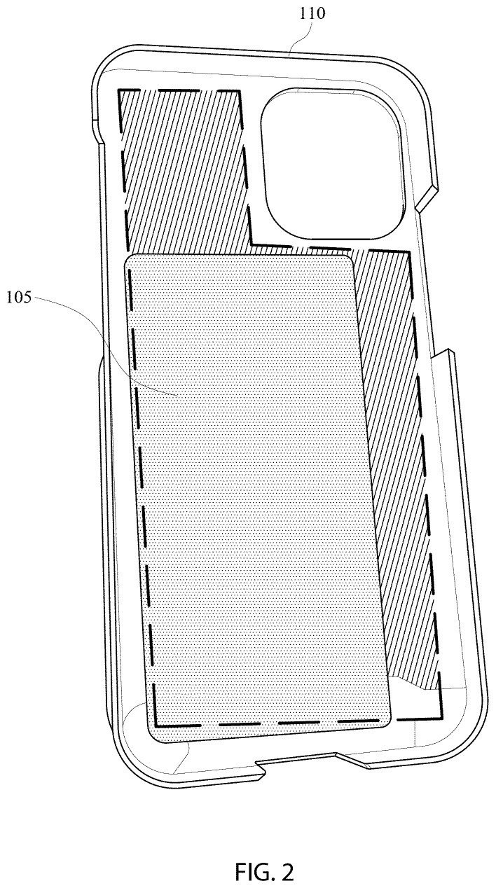

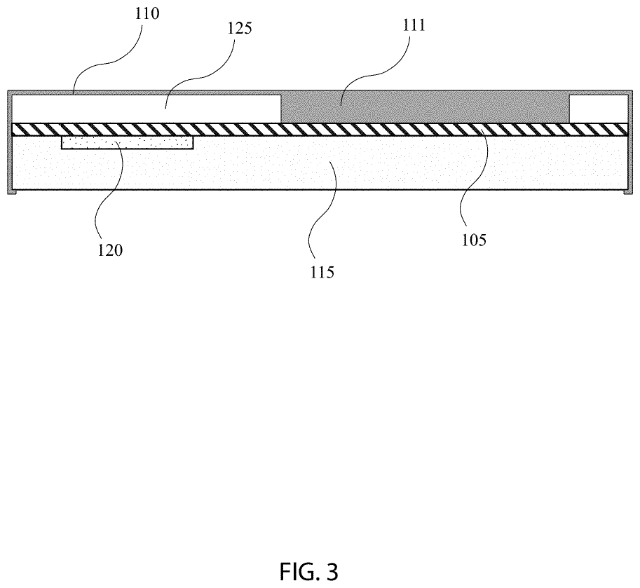

FIG. 1, FIG. 2, and FIG. 3 illustrate a thermal ground plane 105 embedded within a phone case 110 that incases a phone 115. The thermal ground plane 105, for example, may be embedded within the phone case 110. The thermal ground plane 105, for example, may transfer heat from the phone 115 and/or cool the phone 115. The thermal ground plane 105, for example, may cool a specific hotspot 120 of the phone 115. The hotspot may comprise a portion of the phone that includes various integrated circuits. The phone case 110 may, for example, have one or more detents 111 that extend from an interior surface of the phone case 110. The one or more detents 111 may create a gap 125 between the phone case 110 and the thermal ground plane 105. The gap 125 may, for example, enhance insulation effects in one or more areas.

The thermal ground plane 105 may include an evaporator region disposed on a surface of the thermal ground plane 105 that faces an inner surface of the phone case 110 and a condenser region on an opposite surface of the thermal ground plane 105 that faces an outer surface of the phone case 110. The condenser region, for example, may expand across a portion of the opposite surface, substantially all of the opposite surface, and/or a majority of the opposite surface.

The thermal ground plane 105, for example, may spread heat across the surface of the phone case 110. This may, for example, reduce the heat flux and/or the amount of heat emitted from hotspot 120. For example, heat from a hotspot on the phone may spread to the evaporator region, which may then be transported through the thermal ground plane and dissipate from the condenser region.

The thermal ground plane 105, for example, may cover all or substantially all of a surface of the phone 115.

An intermediate layer, for example, may be disposed between the thermal ground plane 105 and the phone case 110. The intermediate layer, for example, may comprise one or more of copper, aluminum, etc. The thermal ground plane 105 and/or the phone case 110, for example, may attach to the phone 115 by elastic force around the perimeter of the phone 115, such that the phone case 110 may conform to a specific phone size and shape.

The air gap 125, for example, may disposed on the phone case 110 in the area of the thermal ground plane 105 that is near the hotspot 120 to provide insulation between a hot portion of the thermal ground plan 105 and the phone case 110 to reduce the skin temperature on the phone case 110. The one or more detents 111 may create this air gap 125 and may create other air gaps 125 to provide additional insulation at or near other hot spots in the phone 115.

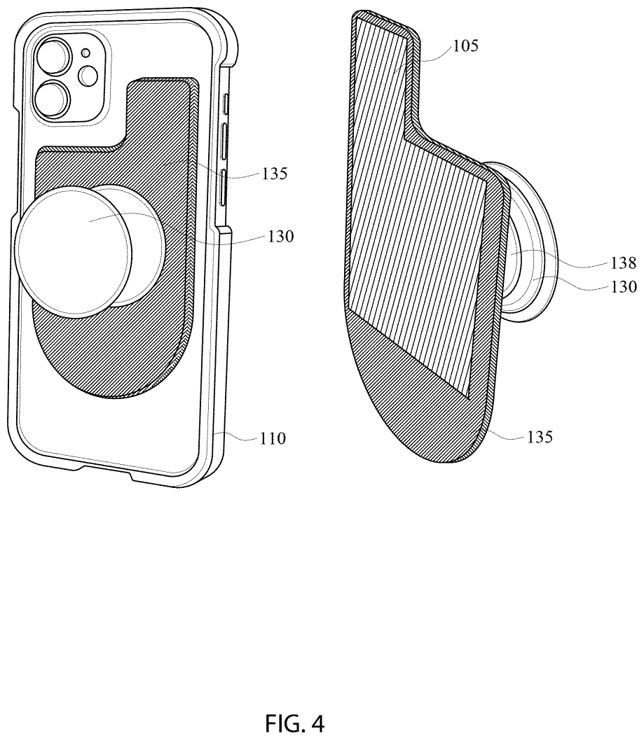

FIG. 4 illustrates an example phone carrier 135 that may be attached with a phone case 110 or directly with a phone. The phone carrier 135, for example, may include an extended handle 130. The phone carrier 135, for example, may have an adhesive the couples the phone carrier 135 with the phone case 110 and/or the phone 115. The phone carrier 135, for example, may include the thermal ground plane 105.

The phone carrier 135, for example, may be integral with the phone case 110 or separate from the phone case 110.

The extended handle 130, for example, may include flat disc shaped portion that extends or may be extended from the phone carrier 135 via a pillar or column 138.

Additionally or alternatively, the extended handle 130, for example, may have a magnetically active region that may magnetically attach to a magnetically active region in the phone 115. Additionally or alternatively, the thermal ground plane 105 may adhere to the surface of the phone 115 (or the phone case 110) by an adhesive.

The thermal ground plane 105 and phone case 110, for example, may be coupled to each other by adhesive. The thermal ground plane 105 and phone case 110, for example, may be coupled to each other by pressure seal. The thermal ground plane 105 and phone case 110, for example, may be coupled to each during manufacture.

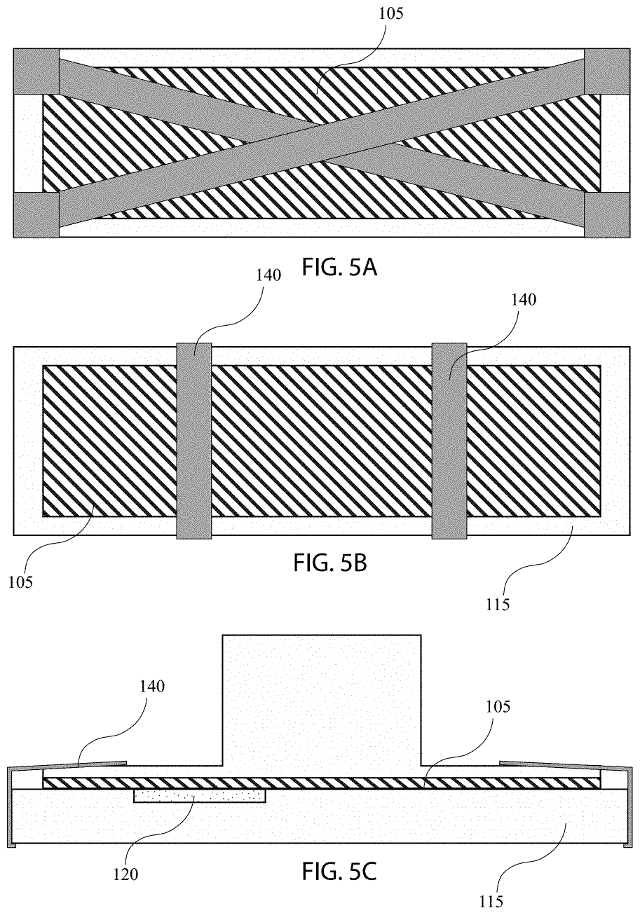

FIG. 5A, FIG. 5B, and FIG. 5C illustrate an example phone case 110 with elastic-actuated clips 140, which can attach a thermal ground plane 105 to the back and/or edge of a phone 115. An elastic-actuated clips 140, for example, may include spring-powered clips, “living hinges,” or elastic material. A clip elastic-actuated clips 140, for example, may attach to the long-edge of the phone, the short edge, both edges, corners, or combinations.

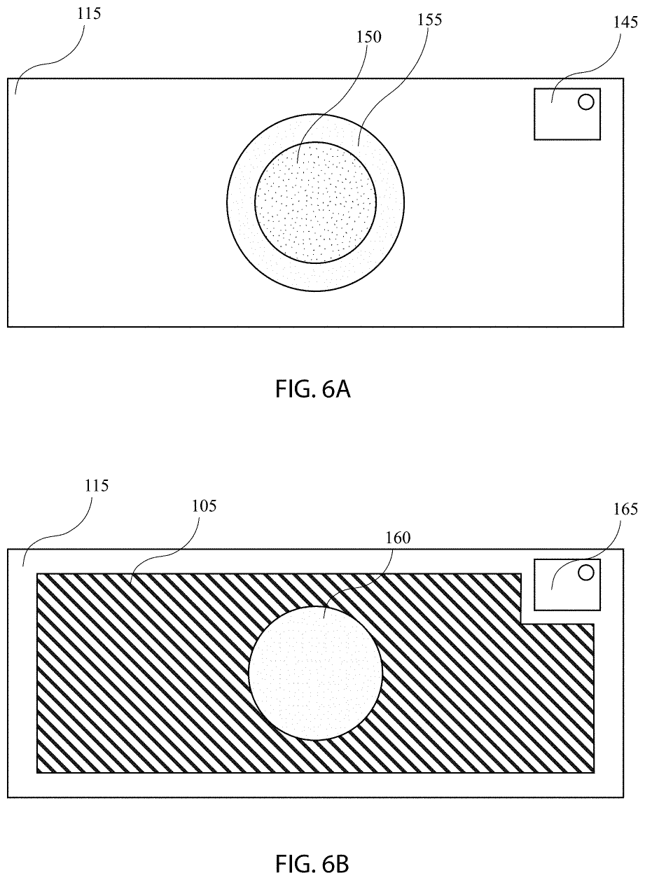

FIG. 6A and FIG. 6B illustrates a phone case 110 having a thermal ground plane 105 that accommodates wireless charging through the phone case 110. Wireless charging of phones may be achieved through electromagnetic induction between a transmitter external to the phone and a receiver within the phone in a charging region. Such electromagnetic induction may create a radio-frequency oscillation of electrical and magnetic fields. However, in typical phones and/or phone cases such electrical and magnetic fields may be blocked by a conductive layer that is placed between the transmitter and the receiver (e.g., metal film), which may act as a Faraday cage.

FIG. 6A illustrates a phone 115 with a wireless charging region 150 and a camera 145. The wireless charging region 150, for example, may include a region with one or more magnets that can be used for attaching accessories with a phone case. The wireless charging region 150, for example, may include the MagSafe or MagSafe Charger on various Apple products.

FIG. 6B illustrates thermal ground plane 105 that accommodates the wireless charging region 150 and/or the camera 145. To accommodate the wireless charging region 150 the thermal ground plane 105, for example, may have a cutout 160 that has a diameter substantially similar to or slightly larger than the diameter of the wireless charging region 150. The cutout 160, for example, may comprise a hole in the thermal ground plane 105. The cutout 160, for example, may comprise a region without metal. The cutout 160 may be aligned with the wireless charging region 150 when the thermal ground plane 105 is coupled with the phone 115. The cutout 160, for example, may comprise a hole in the thermal ground plane 105. The cutout 160, for example, may be dielectric or RF-transparent.

To accommodate the camera 145 the thermal ground plane 105, for example, may have a cutout 165 that is sized and/or aligned with the camera 145 of the phone 115.

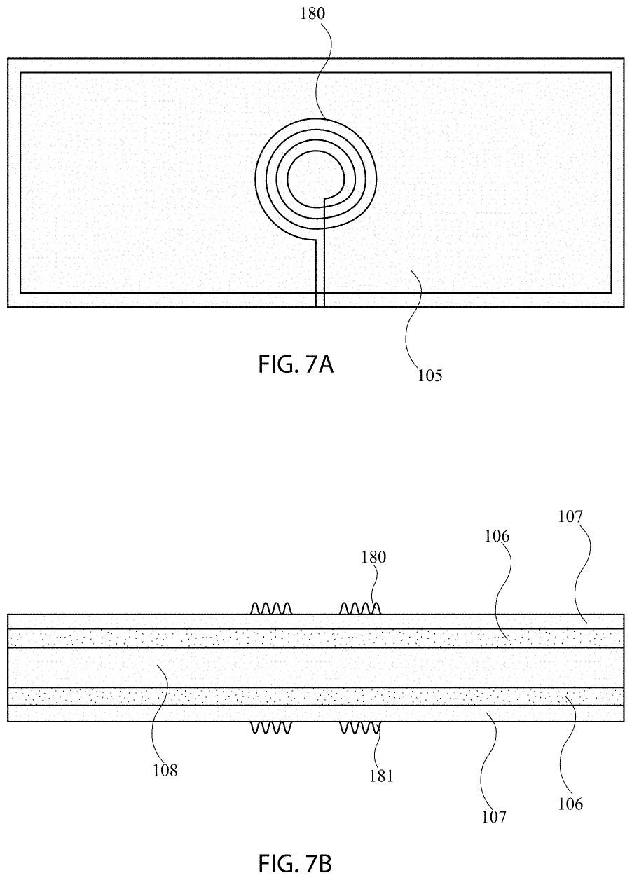

FIG. 7A and FIG. 7B illustrate a thermal ground plane 105 with a transmitter antenna 180 and/or a receiver antenna 181. The transmitter antenna 180 and/or the receiver antenna 181 may act as a waveguide for RF signals and/or power transfer for wireless charging though one or more layers that would normally block RF signals and/or wireless charging. The transmitter antenna 180 and/or the receiver antenna 181, for example, may be electrically connected with each other. The transmitter antenna 180 and/or receiver antenna 181, for example, may be connected to intermediate electrical components that may, for example, modify the waveform being transmitted and/or received. The transmitter antenna 180 may be disposed on an interior surface of the thermal ground plane 105 and/or the receiver antenna 181 may be disposed on an exterior surface of the thermal ground plane 105.

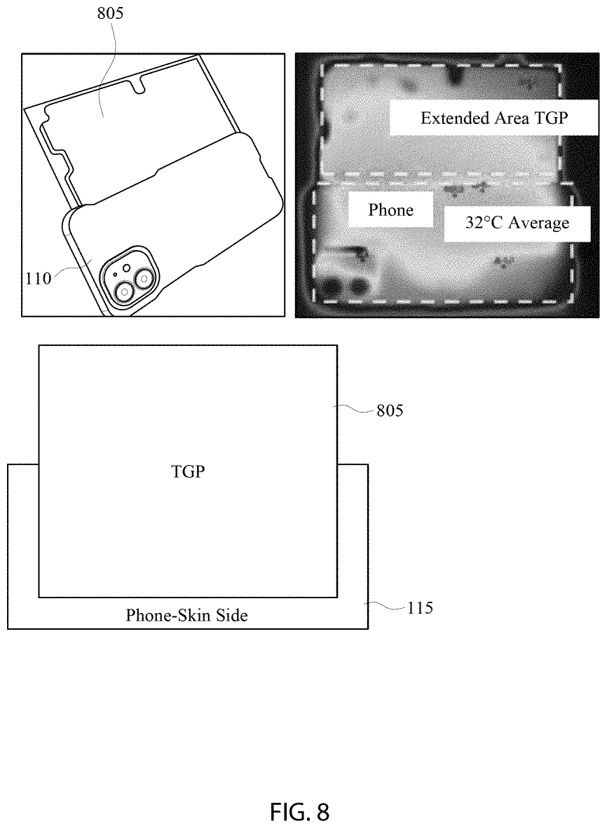

FIG. 8 illustrates an extended area thermal ground plane 805. A case 110, for example, may have a surface area that is larger than the surface area of the phone 115. The larger surface area of the thermal ground plane 805 may allow for additional convection to occur. The extended surface area, for example, may extend in a plane parallel to the phone screen. The extended area thermal ground plane 805, for example, may bend to form a bracket. The bracket may, for example, create a fin that extends out the backend of the phone 115. An extended area thermal ground plane 805 and/or a bracket TGP may be used together. A thermal ground plane 805, for example, may have a plurality of bends in a constrained volume.

The thermal ground plane 105 may include a first and second casing 106, for example, with a polymer laminate 107 on the exterior of the thermal ground plane 105. The thermal ground plane 105, for example, may include one or more vapor transport layers and/or one or more liquid transport layers, evaporator regions, condenser regions, etc. The thermal ground plane 105, for example, may include various structures

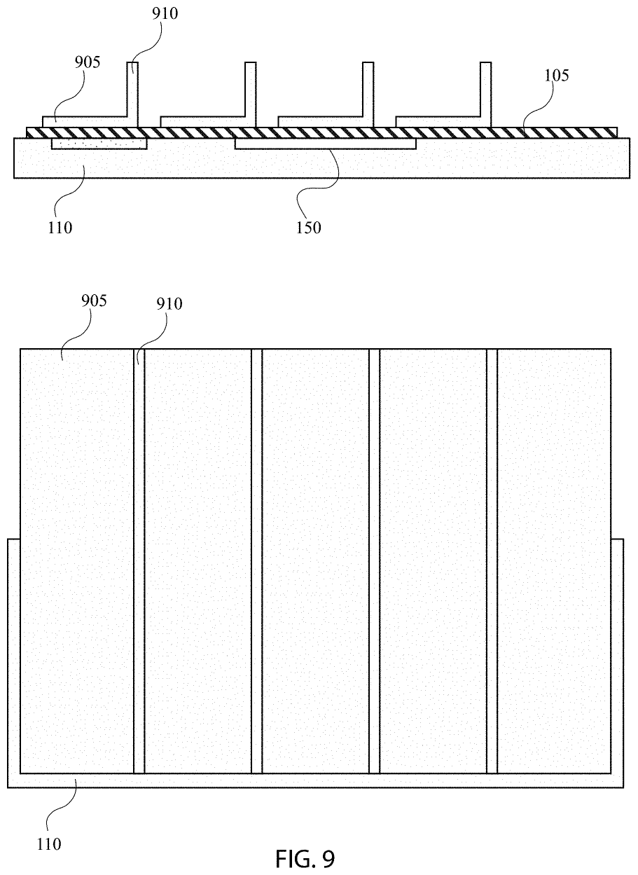

FIG. 9 illustrates a thermal ground plane 905 that includes a first thermal ground plane 105 and a plurality of fins 910 (e.g., metallic fins or graphite fins) to increase the surface area of the thermal ground plane 905. A thermal ground plane 905 may or may not include an extended surface and/or may include one or more heat pipes with or without fins.

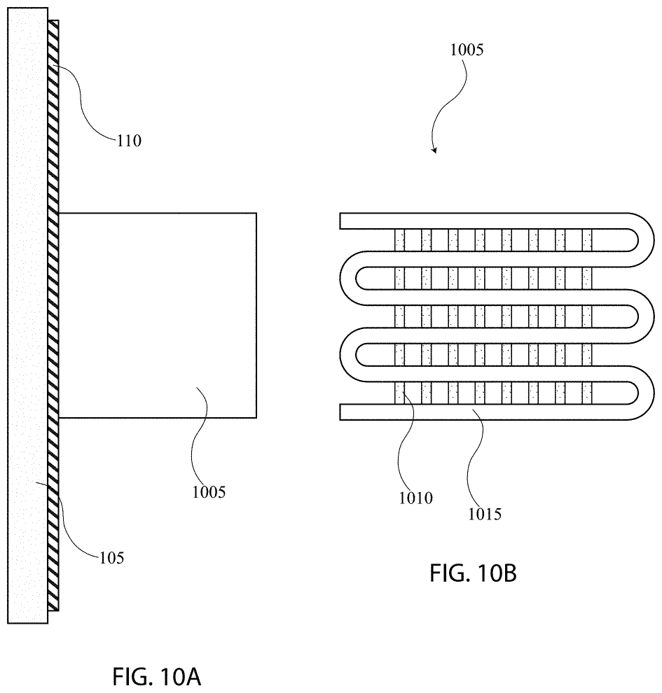

FIG. 10A illustrates a thermal ground plane 105 (either extendable or non-extendable) that includes detachable heat sink 1005. The detachable heat sink 1005, for example, may include a pin or fin heat sink that may be comprised of metal.

FIG. 10B illustrates a detachable heat sink 1005 that includes a folded thermal ground plane 1015 and/or a plurality of fins 1010.

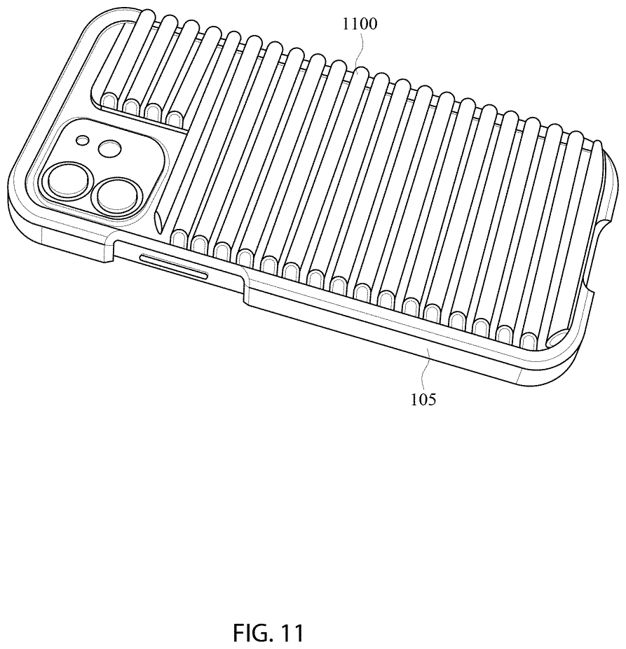

FIG. 11 illustrates a thermal ground plane 1100 with a plurality of detachable fins.

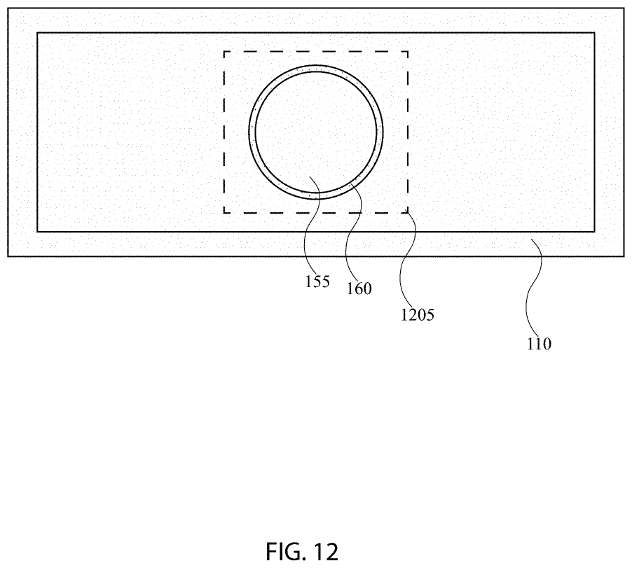

FIG. 12 illustrates a phone case 110 that can be magnetically attached with a detachable heat sink. 1005. A detachable heat sink 1005, for example, may be attached with the phone or phone case 110 via a magnetic mechanism 155 on the phone 115 such as, for example, mag-safe. The dashed line 1205 illustrates the footprint of the detachable heat sink 1005.

A detachable heat sink 1005, for example, may be attached with the phone or phone case via clips, suction, screws, etc. The detachable heat sink 1005, for example, may be attached directly with the phone edges and/or may be located in various locations on the surface of the phone.

A phone case, for example, may include a pop-out unit and the detachable heat sink 1005 may attach to the pop-out unit or be part of or integrated with the pop-out unit.

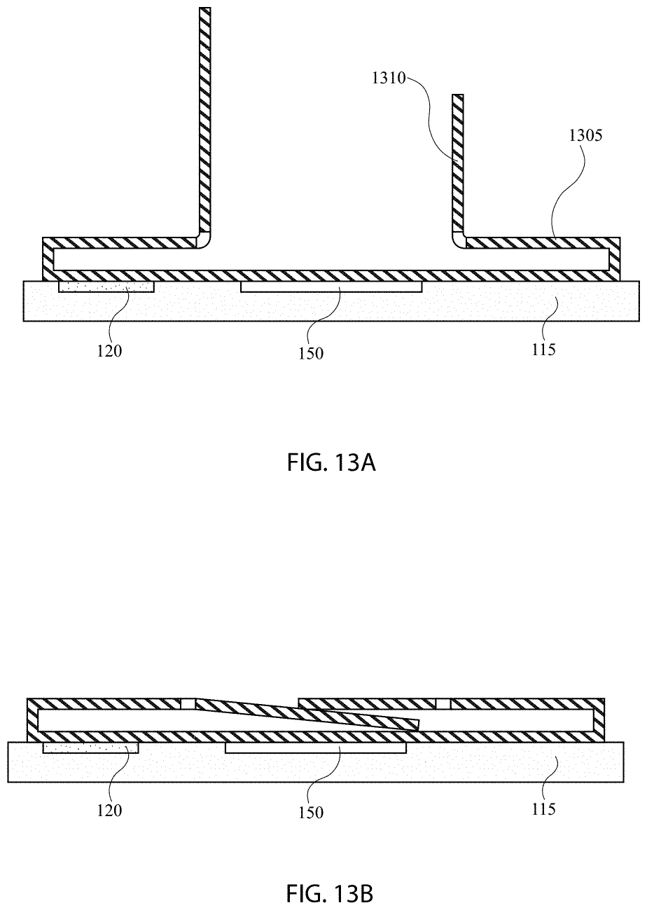

FIG. 13A and FIG. 13B illustrate a foldable thermal ground plane 1305 with a foldable extended area 1310. The foldable extended area 1310, for example, may allow the foldable thermal ground plane 1305 to have an extended surface as shown in FIG. 13A and have a compact size when not deployed as shown in FIG. 13B.

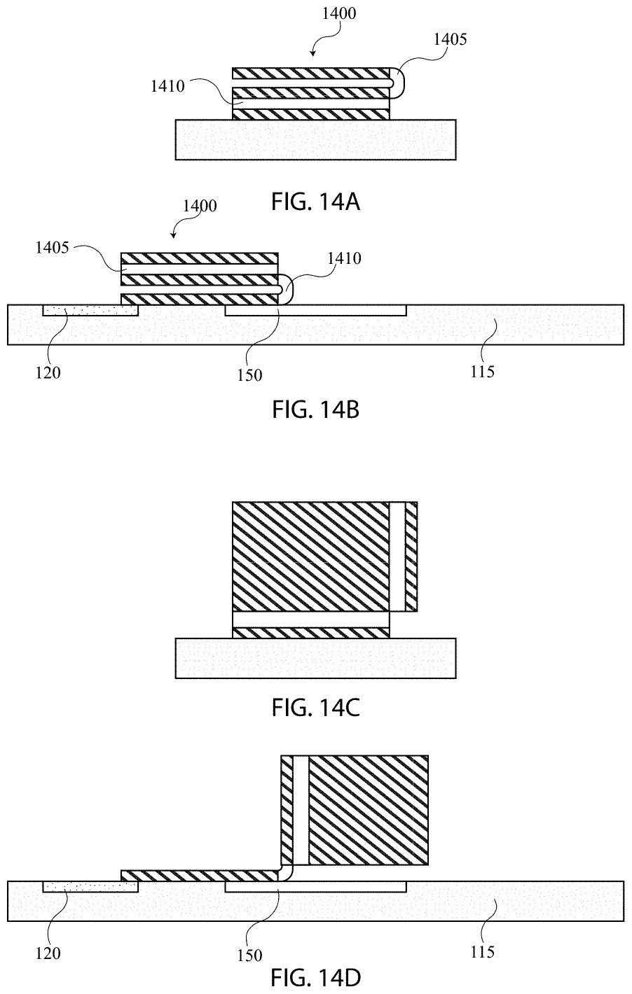

FIG. 14A, FIG. 14B, FIG. 14C, and FIG. 14D illustrate a foldable thermal ground plane 1400 with multiple folds. The foldable thermal ground plane 1400 includes a first fold 1405 and a second fold 1410. FIG. 14A and FIG. 14B illustrate the first fold 1405 in the folded state and FIG. 14C and FIG. 14D illustrate the TGP in the unfolded state.

A Foldable TGP, for example, may be coupled with a case mechanisms. A foldable TGP may, for example, may be attached to a spring-loaded case that may extend a TGP in response to the push of a button. A foldable TGP may, for example, may be attached to a case with a ratchet shape to hold the TGP once it is extended. A foldable TGP may, for example, be attached to an extended leg or structure that can hold the TGP once extended. A foldable TGP may, for example, be coupled with a case via rotating mechanics.

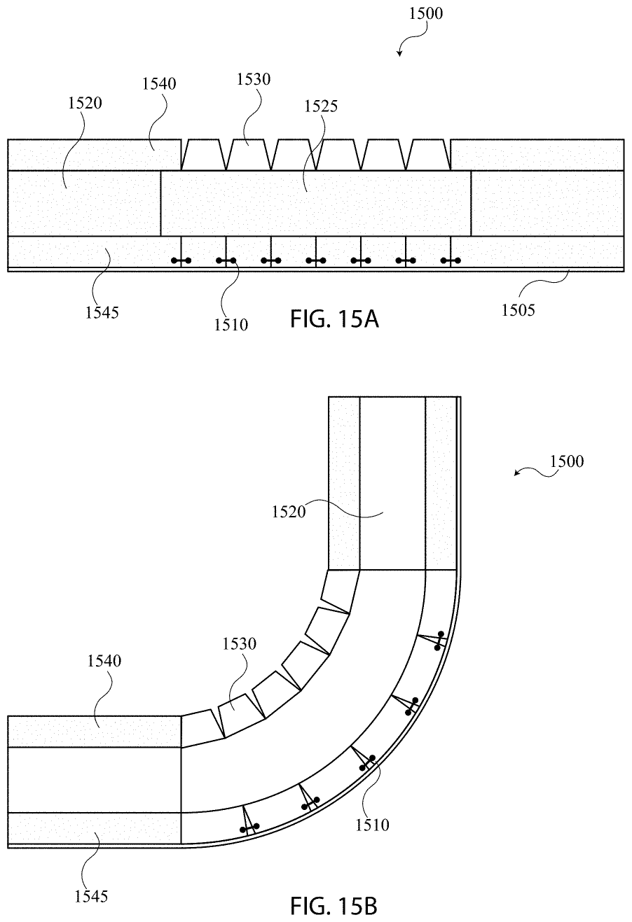

FIG. 15A and FIG. 15B illustrate a foldable TGP case 1500 that may include a thermal ground plane 1520 sandwiched between a top layer 1545 and a bottom layer 1540. The top layer 1545 and/or the bottom layer 1540 may include a series of trapezoidal segments 1530 surrounding a foldable region 1525 that may allow at least a portion of the foldable TGP case 1500 to fold or bend. The top layer 1545 and/or the bottom layer 1540 may, for example, include pivot joints 1510 disposed between trapezoidal segments 1530. The foldable TGP case 1500, for example, may include an elastic material 1505 to allow for a prescribed bend radius.

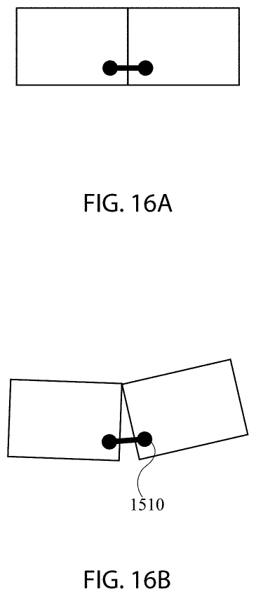

FIG. 16A and FIG. 16B illustrate the trapezoidal segments 1530 with the pivot joints 1510 in the unfolded and folded configuration respectively.

The folding region of a foldable TGP, for example, may extend across the hinge of a foldable electronic device, such as, for example, a laptop, tablet, foldable smartphone, etc. The radius of curvature of the foldable TGP, for example, may be different from the radius of bending associated with the hinge of the foldable electronic device, and in such a case there may be a mismatch in bending length because bending length is the product of bend angle and radius. For example, one side of the TGP may be mechanically anchored with a stiff region of the electronic device (e.g., attached with a portion of the electronic device that is not part of the hinge, attached with a non-hinge region, attached with a portion of the case, glued to a chip, glued to a circuit board, etc.) and on the other side of the TGP may be anchored with the electronic device via a stretchable material that is anchored to a stiff region of the electronic device. The two sides of the TGP may be on opposites sides of a bending region in the TGP. When bending creates a mismatch in length in the TGP, the length, for example, may be absorbed by the stretchable material. The TGP, for example, may be free to slip across the surface which it is not anchored to. The stretchable material, for example, may be an elastic rubber, a metallic spring, a flexure, etc. The stretchable material, for example, may be embedded in a case. The stretchable material, for example, may be anchored to a case of the electronic device, which may create an external fin. The side of the electronic device which the TGP is anchored to (e.g., without a stretchable material) may include the majority of heat generating electronic elements such as, for example, CPU chips, and the mechanical anchoring may facilitate a thermal interface.

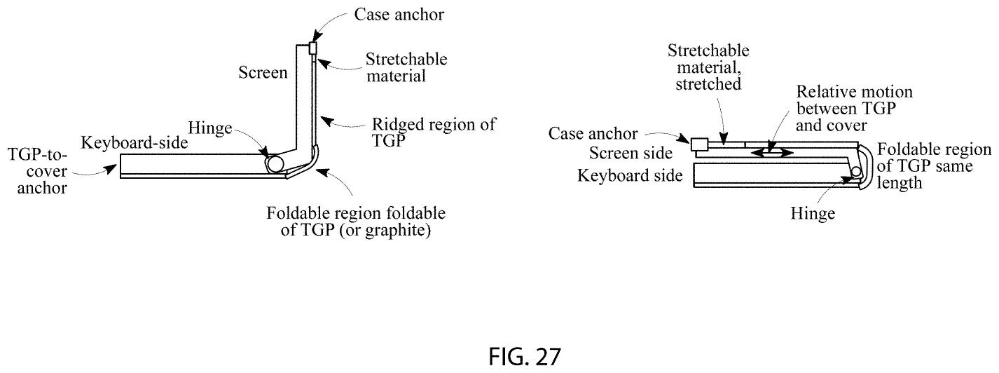

FIG. 27 is a side-view of an example foldable device with a TGP having a foldable region that is attached with the TGP via a stretchable material. The TGP, for example, may include a TGP with ridges. The TGP, for example, may be part of the case and/or on the external surface of the case of the electronic device. The foldable region of the TGP may be located near a hinge in the electronic device.

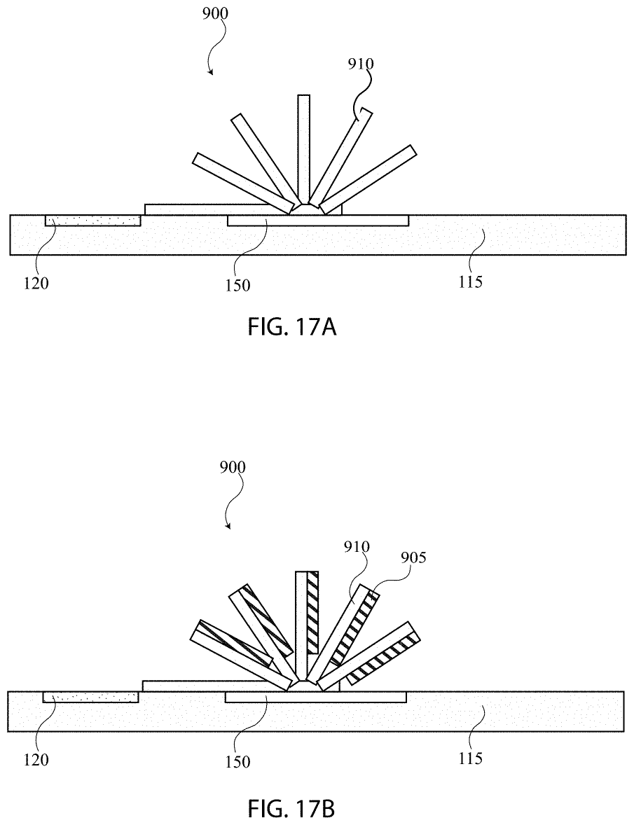

FIG. 17A and FIG. 17B illustrate foldable TGPs with a complicated mechanism 900. A complicated mechanism may include a plurality of fins 910 each of which includes a folding region. When unfolded, the plurality of fingers may have different bend angles that may increase the surface area and/or the effective heat transfer coefficient. A plurality of fins, for example, may be attached to each finger to increase the surface area. Fins, for example, may be made of aluminum, copper, graphite, or an additional thermal ground plane 905.

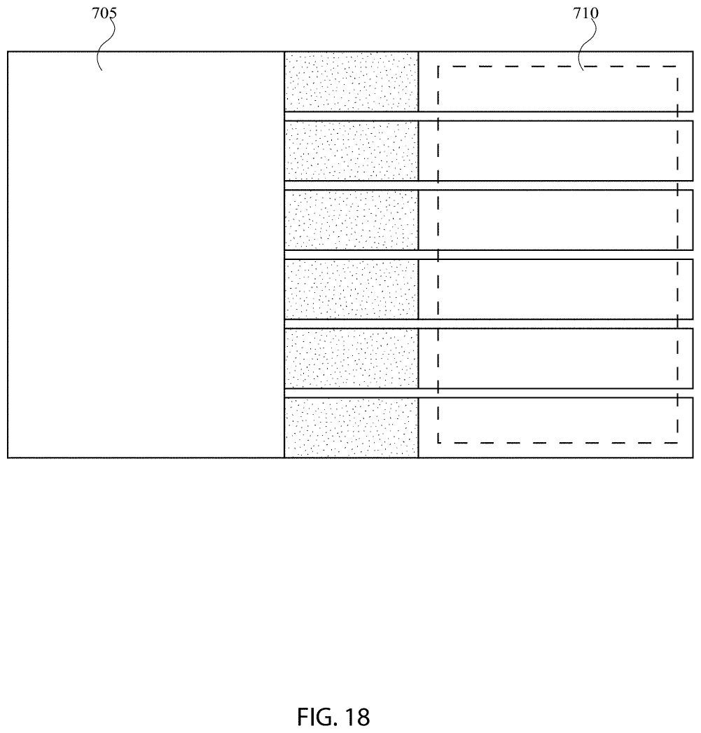

FIG. 18 illustrates two thermal ground planes 705, 710 with multiple fingers and/or fins laying opposite and about each other when flat that may unfold to increase surface area. These TGPs, for example, may have flexible regions at different lengths along the fingers. This may, for example, allow the fingers to bend up to and including 50-180 degrees out from the phone at different locations as measured from the back surface of the phone. The folding region of a TGP may include folding fins attached to it, to extend the area when it is unfolded, but lay flat when the TGP is flat. These fins, for example, can be made of flexible thermally conductive material such as copper, aluminum, graphite, or a separate foldable TGP.

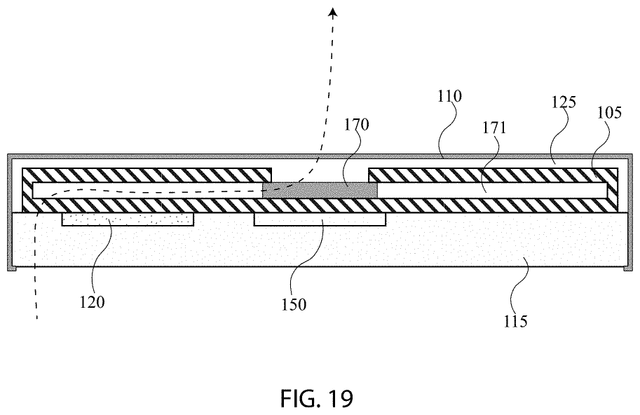

FIG. 19 illustrates a phone case 110 with a thermal ground plane 105 and an integrated fan 170. The thermal ground plane 105 may include an air gap 171 within the thermal ground plane 105. There may be another air gap between the thermal ground plane 105 and the phone case 110.

The integrated fan 170 may, for example, increase airspeed around a phone, which may increase the effective heat transfer coefficient. The integrated fan 170, for example, may pull air through vents in the perimeter of the phone 115 and/or phone case 110 and expel air out the center of the back of the phone 115 and/or phone case 110. The airflow can go the other direction. The integrated fan 170 may thin, such as, for example, less than about 10, 5, 3, 1, etc. mm. The integrated fan 170 can be a radial blower, or an axial fan. The integrated fan 170 may be powered wirelessly from the phone or powered with a battery or be powered through wired contact.

The integrated fan 170, for example, may be removable or disconnected from the phone case 110. The integrated fan 170, for example, may be integrated into a heat sink such as, for example, a heat sink with one or more fans.

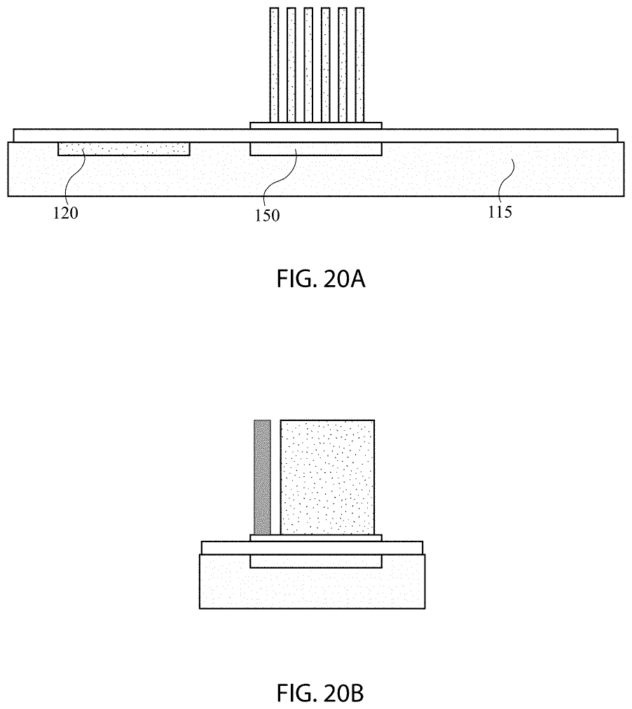

The integrated fan 170, for example, may remain in plane during some operation and may fold out in other operations to enhance air flow. FIG. 20A and FIG. 20B shows the fan folded out in one direction, while folding TGPs create fold-out fins in a perpendicular direction.

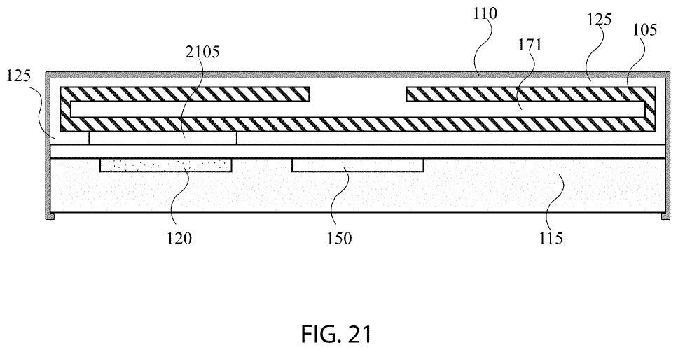

FIG. 21 illustrates a TGP with an integrated thermoelectric cooler 2105. In some embodiments, a solid-state thermoelectric cooler 2105 may be disposed in the case 110 between the thermal ground plane 105 and the phone 115. The cold side of the thermoelectric cooler 2105, for example, may be in contact with the hotspot 120. The hot side of the thermoelectric cooler 2105, for example, may be in contact with the thermal ground plane 105. This configuration, for example, may reduce the junction temperature of the phone processor (e.g., the hotspot 120), which may reduce the temperature on the screen side of the phone 115. As a possible consequence, the temperature on the case side, for example, may be greater than with a non-thermoelectric cooler solution. This may, for example, make both sides of the phone closer in temperature. The thermal ground plane 105 may or may not be in contact with the phone. Heat may be removed from that thermal ground plane 105 by the cold-side of the thermoelectric cooler 2105, while the hot-side of the thermoelectric cooler 2105 is cooled by convection. In some embodiments, the thermoelectric cooler 2105 may be powered by plugging into an external power source, by internal batteries, or wirelessly from the phone.

The case may include an air-gap 125 that may allow air to flow to the hot surface of the thermoelectric cooler 2105. This may also prevent the outer edge of the case 110 from heating to uncomfortable levels. The hot-side of the thermoelectric cooler 2105, for example, may be in contact with a hot TGP, while the cold side of the thermoelectric cooler 2105 may be in contact with a cold TGP. The cold TGP may cool the phone as well as the case while the hot TGP may heat up air within the case to increase natural convection caused by buoyancy, as in FIG. 21.

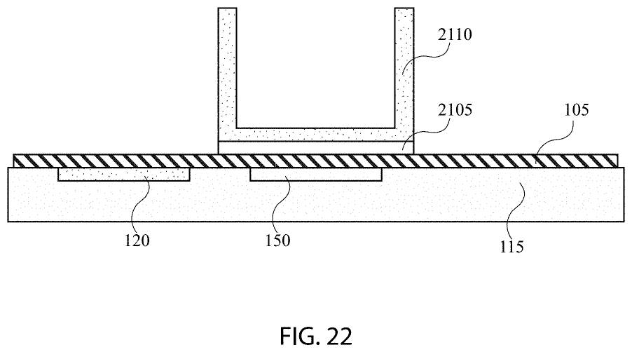

FIG. 22 shows a detachable thermoelectric cooler 2105 coupled with thermal ground plane 105. The thermoelectric cooler 2105 may be detachable from the case 110, which may include the thermal ground plane 105. The thermoelectric cooler 2105, for example, may be affixed to the case 110 and a heatsink coupled with the hot side of the thermoelectric cooler 2105 may be detachable. The TGP may, for example, be attached directly to the phone through various techniques such as, for example, adhesive, magnets, suction, etc., with or without an external case.

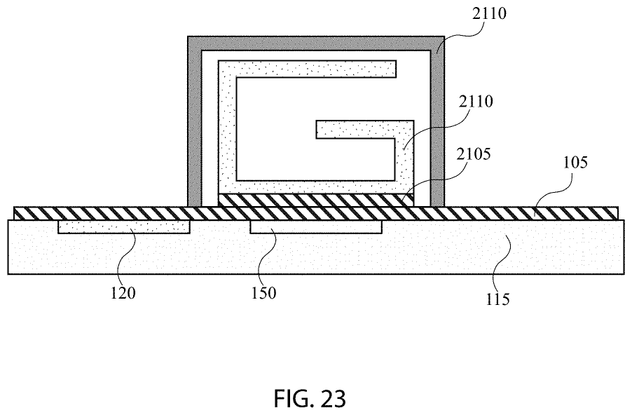

FIG. 23 illustrates a heatsink 2110 for the thermoelectric cooler 2105 may be open on 2 sides as an air inlet and air outlet but enclosed on the other sides to prevent skin contact to the surface which may be hotter than ergonomic limits. In some embodiments, the heatsink is composed of metal fins or TGP fins. The heatsink may be foldable and/or lie flat when it is not deployed. The heatsink may include a fan.

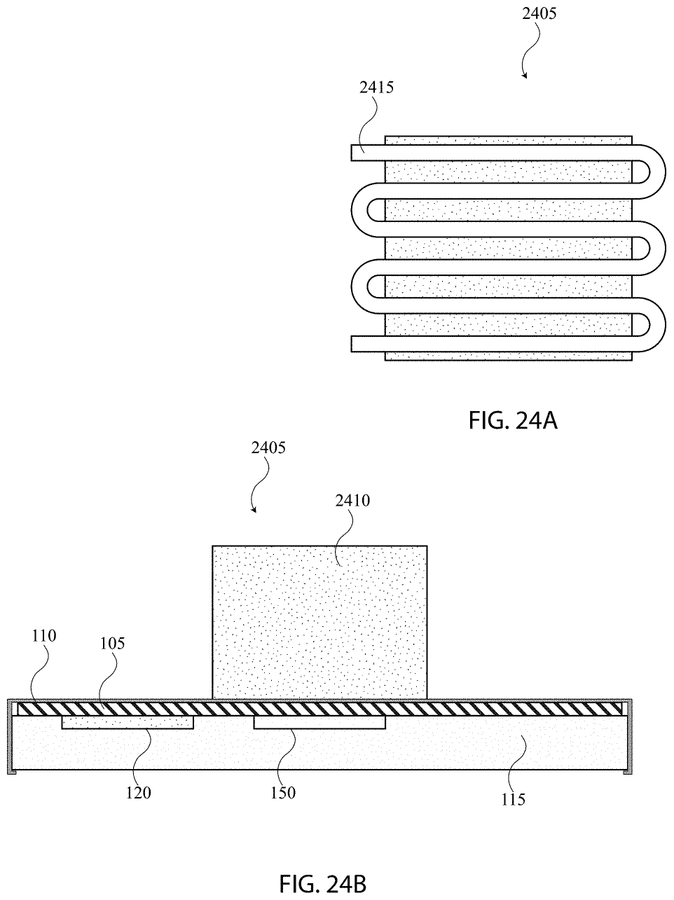

FIG. 24A illustrates a detachable unit 2405 that includes phase change material 2410 and a thermally conductive material 2415 (e.g., copper, aluminum, graphite, heat pipes, TGPs, etc.) disposed through the phase change material 2410. The thermally conductive material, for example, may be in the form of solid wires, foils, meshes, foams, etc.

FIG. 24B illustrates the detachable unit 2405 coupled with the case 110. The case 110 includes thermal ground plane 105 and the case 110 is coupled with the phone 115. The detachable unit 2405, for example, absorbs heat from the thermal ground plane 105 and the case 110. During use, for example, when a first detachable unit 2405 has been fully melted by absorbing heat from the thermal ground plane 105, it can be detached and replaced with a second detachable unit 2405. The thermally conductive material may include aluminum, graphite, copper, heat pipes or TGPs; the form of the thermally conductive material may include foils, wires, mesh, or foams.

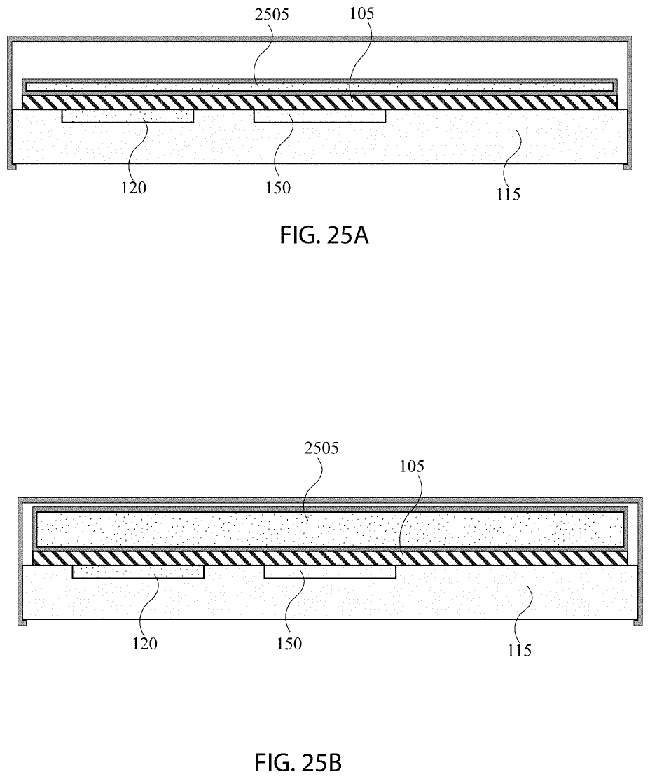

FIG. 25A illustrates a thermal ground plane 105 may be coupled with a vessel 2505 that is filled with a low-boiling-point material (e.g., hydrofluoroether 7000). As the vessel is heated above the boiling point of the low-boiling point material (e.g., 30 C) by the thermal ground plane 105, the vessel 2505 may expand as shown in FIG. 25B, while heat is absorbed by the evaporation/boiling process.

As another example, a phone case may include an open reservoir for liquid. The liquid, for example, may be water or a similar liquid. The liquid, for example, may be held in the reservoir in a wick, such as a mesh. The liquid, for example, may be in a volume with an open top. When heat is applied to the water from the TGP, some of it evaporates and the phase change enthalpy of evaporation acts to cool the case system. The vapor vents into the ambient room. The case, for example, may also include a thermoelectric cooler element, thermally connected on one side to the phone and on the other side to the water reservoir. This thermal contact, for example, may be facilitated by direct contact, by TGPs, or by other thermally conductive layers. When the phone is running and needs to be cooled, for example, the thermoelectric may be run with its polarity aimed at cooling the phone and heating the water side. When the phone is not running but rather charging (e.g., overnight), for example, the thermoelectric cooler can run with reversed polarity such that it cools the water reservoir and heats the phone. And atmospheric water may be collected by condensation and the reservoir may be filled.

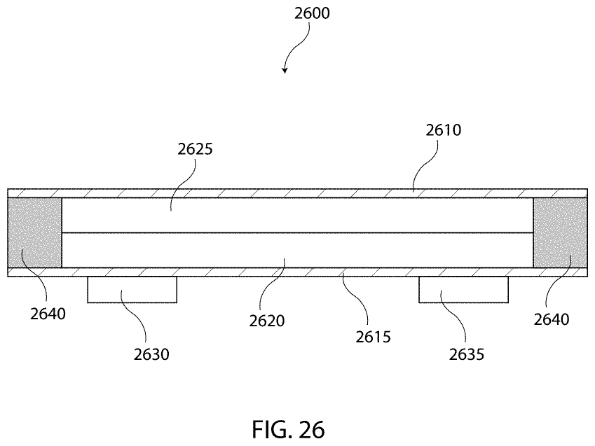

FIG. 26 is a side view illustration of an example thermal ground plane 2600. thermal ground plane 2600 or variations thereof may be used for any thermal ground plane described in this document. The thermal ground plane 2600 includes a first casing 2610, a second casing 2615, a liquid transport layer 2620, and/or a vapor transport layer 2625. The thermal ground plane 2600, for example, may operate with evaporation, vapor transport, condensation, and/or liquid return of a heat transfer fluid for heat transfer between the evaporation region 2630 and the condensation region 2635. The heat transfer fluid (HTF) may include, for example, water and/or ammonia in both liquid and vapor phases. The structures and/or characteristics of the thermal ground plane 2600 may be applied to any embodiment or example described within this document.

The first casing 2610, for example, may include copper, polymer, atomic layer deposition (ALD) coated polymer, polymer-coated copper, copper-cladded Kapton, etc. The second casing 2615, for example, may include copper, polyimide, polymer-coated copper, copper-cladded Kapton, steel, copper-clad steel, etc. The first casing 2610 and/or the second casing 2615, for example, may include a laminate of copper, polyimide, and copper. The first casing 2610 and the second casing 2615, for example, may be sealed together using solder, laser welding, ultrasonic welding, electrostatic welding, or thermocompression bonding (e.g., diffusion bonding) or a sealant 2640. The first casing 2610 and the second casing 2615, for example, may include the same or different materials.

The first casing 2610 and/or the second casing 2615 may comprise at least three layers of copper, polyimide, and copper. The polyimide, for example, may be sandwiched between two copper layers. The copper layers on the first casing and/or the second casing, for example, may can be replaced with atomic layer deposition (ALD) nano-scaled layers such as, for example, Al₂O₃, TiO₂, SiO₂

The evaporation region 2630 and the condensation region 2635 may be disposed on the same layer: the first casing 2610 or the second casing 2615. Alternatively, the evaporation region 2630 and the condensation region 2635 may be disposed on different layers of the first casing 2610 and the second casing 2615.

The vapor transport layer 2625 and/or liquid transport layer 2620 may be formed from an initial structure (e.g., a mesh, and/or an array of pillars, etc.) that has been deformed into various geometric shapes that may improve reliability of structure during folding and unfolding, thermal transport, the flow permeability, the capillary radius, the effective thermal conductivity, the effective heat transfer coefficient of evaporation, and/or the effective heat transfer coefficient of condensation. The initial structure may include multiple layers of mesh. The vapor transport layer 2625 and/or liquid transport layer 2620 may comprise structures or layers that are structurally or physically different.

The outer periphery of the first casing 2610 and the outer periphery of the second casing 2615 may be sealed such as, for example, hermetically sealed.

Various embodiments or examples described in this disclosure include a mesh, which may include any or all of the following. A mesh, for example, may comprise copper and/or stainless steel. A mesh, for example, may include a material having pores that have a dimension of about 10 to 75 μm. For a nonporous mesh, for example, the material may have pores that a have a dimension of about 0.2 to 10 μm. A mesh, for example, may include a material that includes either or both metal and polymer. A mesh, for example, may be highly stretchable, such as, for example, stretchable without plastic deformation, which may, for example, reduce the stress when folded and/or may prevent the formation of wrinkles and blocking of vapor flow. A mesh, for example, may be electrically conductive and/or may be coated in a dielectric material such as, for example, to prevent plating of material into the pores away from the anchors. The pores in a mesh, for example, may be made from polymer, ceramic, other electrically insulating materials or electrically conductive material and/or may be covered by an electrically insulating layer. A mesh, for example, may include woven wires, non-woven wires, or porous planar media. A mesh, for example, may include an ALD-coated polymer without any metal. A mesh, for example, may include a Cu-clad-polyimide laminate material. A mesh, for example, may include woven wires, non-woven wires, and/or porous planar material. A mesh, for example, may include a copper mesh or non-copper mesh such as, for example, a polymer mesh or a stainless steel mesh. The mesh, for example, may be encapsulated by hydrophilic and anti-corrosion hermetic seal. A mesh, for example, may include any woven or nonwoven material.

A mesh, for example, may have a thickness of about 10 μm to about 200 μm. A woven mesh, for example, may have a thickness of about 125, 100, 75, or 50 μm. A porous mesh (e.g., a nanoporous mesh and/or a non-woven mesh) may have a thickness of about 5, 10, 15, 20, or 25 μm. A mesh, for example, may include a metal foam.

Various embodiments or examples described in this disclosure include an array of pillars, which may include any or all of the following. An array of pillars, for example, may include a plurality of pillars with an evenly or unevenly distributed pattern. An array of pillars, for example, may include pillars comprising polymer. An array of pillars, for example, may include pillars comprising metal such as, for example, copper. An array of pillars, for example, may include pillars coated with a coating such as, for example, a ceramic (e.g. Al₂O₃, TiO₂, SiO₂, etc.) or a nano-texture coating. The coating may be applied via defect-free ALD, low-defect density ALD, chemical vapor deposition (CVD), molecular layer deposition (MLD), or other nano-scaled coating processes.

An array of pillars, for example, may can be a pseudo-rectangular array, or a pseudo hexagonal array, or a random array. An array of pillars, for example, may have a center-to-center pitch that is constant across array of pillars. An array of pillars, for example, may include pillars with variable diameters and/or heights. An array of pillars, for example, may have a low density (e.g., far apart) at the condenser, have a higher density at the evaporator, and/or gradual change in density between the condenser and the evaporator.

Various embodiments or examples described in this disclosure include a micro pillar array, which may include any or all of the following. A micro pillar array may be disposed on an array of pillars and the micro pillar array, for example, may include a porous material in which the pore size of the material is substantially smaller than the gap between pillars. A micro pillar array may, for example, include nano-wire bundles, sintered particles, templated grown pillars, inverse opals, etc. A micro pillar array may include solid pillars, which may promote conduction of heat along the length, and outer regions of the micropillar array may be porous to promote wicking. Various embodiments or examples described in this disclosure may include internal TGP structures comprising polymer. These TGP structures may include the first casing, the second casing, a mesh, an array of pillars, arteries, wick, vapor transport structures, etc. Polymer TGP structures, for example, may be coated with defect-free ALD, low-defect density ALD, chemical vapor deposition (CVD), molecular layer deposition (MLD), or other nano-scaled coating processes.

Unless otherwise specified, the term “substantially” means within 5% or 10% of the value referred to or within manufacturing tolerances. Unless otherwise specified, the term “about” means within 5% or 10% of the value referred to or within manufacturing tolerances.

The conjunction “or” is inclusive.

The terms “first”, “second”, “third”, etc. are used to distinguish respective elements and are not used to denote a particular order of those elements unless otherwise specified or order is explicitly described or required.

Numerous specific details are set forth to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

The use of “adapted to” or “configured to” is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included are for ease of explanation only and are not meant to be limiting.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, it should be understood that the present disclosure has been presented for purposes of example rather than limitation, and does not preclude inclusion of such modifications, variations and/or additions to the present subject matter as would be readily apparent to one of ordinary skill in the art.

That which is claimed:

1. A phone case comprising:
a phone case body; and
a thermal ground plane embedded within the phone case body, the thermal ground plan comprising:
a first casing;
a liquid transport layer comprising a mesh or an array of pillars;
a vapor transport layer comprising a mesh or an array of pillars; and
a second casing, an outer periphery of the first casing and an outer periphery of the second casing are sealed together encasing the liquid transport layer, the vapor transport layer, and a heat transfer fluid.

2. The phone case according to claim 1, further comprising a fin that folds or bends outward from the phone case body.

3. The phone case according to claim 1, further comprising a magnetic area that comprises a toroid or donut shape.

4. The phone case according to claim 3, wherein the magnetic area is configured to couple with a magnetic coupler within a phone.

5. The phone case according to claim 1, further comprising one or more wireless charging antennas.

6. The phone case according to claim 1, wherein the thermal ground plane includes an area without a metal that aligns with a wireless charging area of a phone.

7. The phone case according to claim 1, wherein the thermal ground plane includes an area comprising a dielectric or RF-transparent material.

8. The phone case according to claim 7, wherein the area aligns with a wireless charging area of a phone.

9. The phone case according to claim 1, further comprising a handle extending from a back of the phone case.

10. A phone case comprising:
a phone case body;
a thermal ground plane coupled with a surface of the phone case body; and
an aperture that extends through the phone case body and the thermal ground plane for a camera.

11. The phone case according to claim 10, further comprising a magnetic area.

12. The phone case according to claim 11, wherein the magnetic area comprises a toroid or donut shape that surrounds the aperture.

13. The phone case according to claim 10, further comprising one or more wireless charging antennas.

14. The phone case according to claim 10, wherein the thermal ground plane includes an area without a metal.

15. The phone case according to claim 14, wherein the area is configured to align with a wireless charging area of a phone.

16. The phone case according to claim 10, wherein the thermal ground plane includes an area comprising a dielectric or RF-transparent material.

17. The phone case according to claim 10, further comprising a handle extending from a back of the phone case.
